(19) United States
(12) Patent Application Publication
(10) Pub. No.: US 2022/0254642 A1
(43) Pub. Date: Aug. 11, 2022

(54) SELECTIVE DEPOSITION OF TRANSITION METAL-CONTAINING MATERIAL

(71) Applicant: ASM IP Holding B.V., Almere (NL)

(72) Inventors: Elina Färm, Helsinki (FI); Jan Willem Maes, Wilrijk (BE); Saima Ali, Helsinki (FI)

(21) Appl. No.: 17/667,013

(22) Filed: Feb. 8, 2022

Related U.S. Application Data
(60) Provisional application No. 63/148,280, filed on Feb. 11, 2021.

(51) Int. Cl. H01L 21/285; C23C 16/455; C23C 16/30

(52) U.S. Cl. CPC H01L 21/28568; C23C 16/30; C23C 16/45544; C23C 16/45553

(57) ABSTRACT

The current disclosure relates to methods and apparatuses for the manufacture of semiconductor devices In the disclosure, a transition metal-containing material is selectively deposited on a substrate by a cyclic deposition process. The deposition method comprises providing a substrate in a reaction chamber, wherein the substrate comprises a first surface comprising a first material, and a second surface comprising a second material. A transition metal precursor comprising a transition metal halide compound is provided in the reaction chamber in vapor phase and a second precursor is provided in the reaction chamber in vapor phase to deposit a transition metal-containing material on the first surface relative to the second surface. A transition metal compound may comprise an adduct-forming ligand. Further, a deposition assembly for depositing transition metal-comprising material is disclosed.

### CROSS-REFERENCE TO RELATED APPLICATIONS

This application claims priority to U.S. Provisional Patent Application Ser. No. 63/148,280 filed Feb. 11, 2021 titled SELECTIVE DEPOSITION OF TRANSITION METAL-CONTAINING MATERIAL, the disclosure of which is hereby incorporated by reference in its entirety.

### FIELD

The present disclosure relates to methods and apparatuses for the manufacture of semiconductor devices. More particularly, the disclosure relates to methods for selectively depositing a metal-containing material on a surface of a substrate, to layers and structures including the metal-containing material, and to vapor deposition apparatuses for depositing the metal-containing material.

### BACKGROUND

Deposition of metal-containing material can be used in the manufacture of a variety of devices, such as semiconductor devices, flat panel display devices and photovoltaic devices. For many applications, it is often desirable to deposit the metal-containing material on a substrate which may contain surfaces of different compositions.

Advances in semiconductor manufacturing present a need for new processing approaches. Conventionally, patterning in semiconductor processing involves subtractive processes, in which blanket layers are deposited, masked by photolithographic techniques, and etched through openings in the mask. Additive patterning is also known, in which masking steps precede deposition of the materials of interest, such as patterning using lift-off techniques or damascene processing. In most cases, expensive multi-step lithographic techniques are applied for patterning. Selective deposition presents an alternative for patterning, and it has gained increasing interest among semiconductor manufacturers. Selective deposition can be highly beneficial in various ways. Significantly, it could allow a decrease in lithography steps, reducing the cost of processing. One of the challenges with selective deposition is that selectivity for deposition processes are often not high enough to accomplish the goals of selectivity. Surface pretreatment is sometimes available to either inhibit or encourage deposition on a given surface, but often such treatments themselves call for lithography to have the treatments applied or remain only on the surface to be treated.

Thus, there is need in the art for more versatile selective deposition schemes to deposit different materials on various surface material combinations for semiconductor structures.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

In one aspect, a method of selectively depositing transition metal-containing material on a substrate by a cyclic deposition process is disclosed. The method comprises providing a substrate in a reaction chamber, wherein the substrate comprises a first surface comprising a first material, and a second surface comprising a second material, providing a transition metal precursor comprising a transition metal halide compound in the reaction chamber in vapor phase, and providing a second precursor in the reaction chamber in vapor phase to deposit a transition metal-containing material on the first surface relative to the second surface.

In some embodiments, the transition metal halide compound comprises a transition metal chloride or a transition metal iodide or a transition metal fluoride.

In some embodiments, the transition metal in the transition metal halide compound is selected from a group consisting of manganese, iron, cobalt, nickel and copper.

In some embodiments, the transition metal halide compound comprises at least one of a cobalt chloride, a nickel chloride, or a copper chloride, cobalt bromide, a nickel bromide, or a copper bromide, cobalt iodide, a nickel iodide, or a copper iodide.

In some embodiments, the methods according to the current disclosure further comprise contacting the transition metal-containing material with a reducing agent thereby forming an elemental transition metal.

In one aspect, a method of selectively depositing transition metal-containing material on a substrate by a cyclic deposition process. The method comprises providing a substrate in a reaction chamber, wherein the substrate comprises a first surface comprising a first material, and a second surface comprising a second material, providing a transition metal precursor comprising a transition metal compound in the reaction chamber in vapor phase, and providing a second precursor in the reaction chamber in vapor phase to deposit transition metal-containing material on the first surface relative to the second surface, wherein the transition metal compound comprises an adduct-forming ligand.

In some embodiments, the adduct-forming ligand comprises at least one of nitrogen, phosphorous, oxygen, or sulfur.

In some embodiments, the second precursor comprises at least one of an oxygen precursor, a nitrogen precursor, a silicon precursor, a sulfur precursor, a selenium precursor, a phosphorous precursor, a boron precursor, or a reducing agent.

In semiconductor device fabrication processes, for example layers of elemental cobalt metal may be important in such applications as liner layers and capping layers to suppress the electromigration of copper interconnect materials, or to improve adhesion or wetting of copper layers. Indeed, as device feature sizes decrease in advanced technology nodes, elemental cobalt layers may be utilized as the interconnect material or in via's contact holes, replacing the commonly utilized copper interconnects. Cobalt metallic layers may also be of interest in giant magnetoresistance applications and magnetic memory applications. In addition, cobalt thin layers may also be deposited onto silicon gate or source-drain contacts in integrated circuits to form a cobalt silicide upon annealing. Many applications would benefit from the ability to deposit elemental transition metal layers.

Accordingly, cyclic deposition methods for the selective deposition of transition metal-containing layers, and particular for the deposition of cobalt-containing layers are highly desirable. Thus, in yet another aspect, a method of selectively depositing a transition metal layer on a substrate by a cyclic deposition process is disclosed. The method comprises providing a substrate in a reaction chamber, wherein the substrate comprises a first surface comprising a first material, and a second surface comprising a second material. providing a transition metal precursor comprising a transition metal halide compound in the reaction chamber in vapor phase and providing a second precursor comprising a carboxylic acid in the reaction chamber in vapor phase to deposit a transition metal layer on the first surface relative to the second surface. In some embodiments, a transition metal layer may mean a material layer in which there are less than 10 at. % of other elements than the transition metal in question.

In some embodiments, the carboxylic acid comprises from 1 to 7 carbon atoms in addition to the carboxylic carbon.

In some embodiments, the carboxylic acid is selected from a group consisting of formic acid, acetic acid, propanoic acid, benzoic acid and oxalic acid.

In some embodiments, a substantially continuous transition metal layer having a thickness of at least 20 nm may be deposited on a first surface with substantially no deposition on the second surface.

In some embodiments, the transition metal precursor and the second precursor are provided in the reaction chamber in an alternate and sequential manner.

In some embodiments, the selectivity of the method is at least 80%.

In some embodiments, the reaction chamber is purged after providing a transition metal precursor and/or second precursor in the reaction chamber.

In another aspect, a device structure including the transition metal-containing material formed according to the methods disclosed herein is disclosed.

In yet another aspect, a vapor deposition assembly for depositing a transition metal-containing material on a substrate is disclosed. The vapor deposition assembly comprises one or more reaction chambers constructed and arranged to hold a substrate comprising a first surface and a second surface, the first surface comprising a first material and the second surface comprising a second material. The vapor deposition assembly further comprises a precursor injector system constructed and arranged to provide a transition metal precursor and a second precursor in the reaction chamber, a transition metal precursor source vessel constructed and arranged to hold a transition metal precursor and a second precursor source vessel constructed and arranged to hold a second precursor. The transition metal precursor source vessel and the second precursor source vessel are in fluid communication with the reaction chamber, and the transition metal precursor comprises a transition metal halide compound and/or an adduct-forming ligand according to the current disclosure.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIGS. 1A and 1B illustrate a process flow diagram of an exemplary embodiment of a method of depositing a transition metal-containing material on a substrate according to the current disclosure.

FIG. 2 is a schematic presentation of an exemplary embodiment of a method of depositing a transition metal-containing material on a substrate according to the current disclosure.

FIG. 3 presents a process flow diagram of an exemplary embodiment of a method of selectively depositing a transition metal layer on a substrate according to the current disclosure.

FIG. 4 is a schematic presentation of a vapor deposition assembly according to the current disclosure.

### DETAILED DESCRIPTION

The description of exemplary embodiments of methods, structures, devices and apparatuses provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The illustrations presented herein are not meant to be actual views of any particular material, structure, or device, but are merely idealized representations that are used to describe embodiments of the disclosure.

In various methods according to the current disclosure, a substrate is provided in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

### Substrate

As used herein, the term substrate may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

The substrate according to the current disclosure comprises two surfaces, and the transition metal-containing material and the transition metal layer according to the current disclosure are deposited on the first surface relative to the second surface. The substrate may comprise any number of additional surfaces. The first surface and the second surface may be arranged as any suitable pattern. For example, the first surface and the second surface can be alternating lines or one surface can surround the other surface in a plan view. The first and section surfaces can be coplanar, the first surface may be raised relative to the second surface, or the second surface can be raised relative to the first surface. The first and second surfaces may be formed using one or more reaction chambers. The patterned structure can be provided on any suitable substrate.

The first surface and the second surface may have different material properties. In some embodiments the first surface and the second surface are adjacent to each other. The first surface and the second surface may be on the same level or one of the surfaces may be lower than the other. In some embodiments, the first surface is lower than the second surface. For example, in some embodiments, the first surface may be etched to be positioned lower than the second surface. In some embodiments, the second surface may be etched to be positioned lower than the first surface. Alternatively or in addition, the materials of the first surface and the second surface may be deposited as to position the first surface and the second surface on different levels.

The substrate may comprise additional material or surfaces in addition to the first surface and the second surface. The additional material may be positioned between the first surface and the substrate, or between the second surface and the substrate, or between both the first and the second surface and the substrate. The additional material may form additional surfaces on the substrate.

In some embodiments, the first surface is a metal or metallic surface. In some embodiments, the first surface comprises a metal or a metallic material. In some embodiments the metal or metallic surface may comprise metal, metal oxides, and/or mixtures thereof. In some embodiments the metal or metallic surface may comprise surface oxidation. In some embodiments, the first surface consists essentially of, or consists of a metal or of a metallic material. In some embodiments, a metal or metallic surface of a substrate comprises an elemental metal or metal alloy, while a second, different surface of the substrate comprises a dielectric material, such as an oxide. For embodiments in which the first surface comprises a metal whereas the second surface does not, unless otherwise indicated, if a surface is referred to as a metal surface herein, it may be a metal surface or a metallic surface.

In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments the metal or metallic surface may be any surface that can accept or coordinate with the first or second precursor utilized in a selective deposition process as described herein.

In some embodiments, the metal in or on the first surface is a transition metal. In some embodiments, the first surface comprises a transition metal. In some embodiments, the first surface consists essentially of, or consists of at least one transition metal. For example, a metal in or on the first surface may be a group 4-6 transition metal. A metal in or on the first surface may be a group 4-7 transition metal. In some embodiments, a metal in or on the first surface is a group 8-12 transition metal. In some embodiments, a metal in or on the first surface is selected from a group consisting of vanadium (V), niobium (Nb), tantalum (Ta), molybdenum (Mo), tungsten (W), iron (Fe), ruthenium (Ru), cobalt (Co), iridium (Ir), nickel (Ni), copper (Cu), aluminum (Al), gallium (Ga), indium (In) and tin (Sb). In some embodiments, the metal in or on the first surface is selected from a group consisting of Nb, W, Fe, Co, Ni, Cu and Al. In some embodiments, the first surface comprises vanadium. In some embodiments, the first surface consists essentially of, or consists of vanadium. In some embodiments, the first surface comprises niobium. In some embodiments, the first surface consists essentially of, or consists of niobium. In some embodiments, the first surface comprises iron. In some embodiments, the first surface consists essentially of, or consists of iron. In some embodiments, the first surface comprises iridium. In some embodiments, the first surface consists essentially of, or consists of iridium. In some embodiments, the first surface comprises gallium. In some embodiments, the first surface consists essentially of, or consists of gallium. In some embodiments, the first surface comprises indium. In some embodiments, the first surface consists essentially of, or consists of indium. In some embodiments, the first surface comprises tin. In some embodiments, the first surface consists essentially of, or consists of tin. In some embodiments, the first surface comprises copper. In some embodiments, the first surface consists essentially of, or consists of copper. In some embodiments, the first surface comprises tungsten. In some embodiments, the first surface consists essentially of, or consists of tungsten. In some embodiments, the first surface comprises ruthenium. In some embodiments, the first surface consists essentially of, or consists of ruthenium. In some embodiments, the first surface comprises cobalt. In some embodiments, the first surface consists essentially of, or consists of cobalt. In some embodiments, the first surface comprises molybdenum. In some embodiments, the first surface consists essentially of, or consists of molybdenum. In some embodiments, the first surface comprises tantalum. In some embodiments, the first surface consists essentially of, or consists of tantalum. In some embodiments, the first surface comprises aluminum. In some embodiments, the first surface consists essentially of, or consists of aluminum. In some embodiments, the first surface comprises nickel. In some embodiments, the first surface consists essentially of, or consists of nickel. In some embodiments, the metal in or on the first surface is a group 8-12 transition metal or a post-transition metal. In some embodiments, the metal in or on the first surface is selected from a group consisting of aluminum, gallium, indium, thallium, tin and lead. In some embodiments the metal or metallic surface comprises one or more noble metals, such as Ru, Ir or palladium (Pd). In some embodiments the metal or metallic surface may comprise zinc (Zn), Fe, Mn or Mo.

In some embodiments, the transition metal-containing material comprises Co, and the first material comprises, consists essentially of, or consists of Cu. In some embodiments, the transition metal-containing material comprises Co, and the first material comprises, consists essentially of, or consists of Mo. In some embodiments, the transition metal-containing material comprises Ni, and the first material comprises, consists essentially of, or consists of Cu. In some embodiments, the transition metal-containing material comprises Ni, and the first material comprises, consists essentially of, or consists of Co.

In some embodiments, the first surface comprises in situ-grown transition metal nitride. In some embodiments, the first surface consists essentially of, or consists of in situ-grown transition metal nitride. In some embodiments, the first surface comprises in situ-grown titanium nitride. In some embodiments, the first surface consists essentially of, or consists of in situ-grown titanium nitride. In some embodiments, the first surface comprises in situ-grown tantalum nitride. In some embodiments, the first surface consists essentially of, or consists of in situ-grown tantalum nitride. By an in situ-grown transition metal nitride is herein meant transition metal nitride that has not been exposed to ambient atmosphere before selective deposition according to the current disclosure. In some embodiments, by in situ-grown transition metal nitride is meant transition metal nitride that has been grown in the same cluster tool or even in the same chamber in which the selective deposition according to the current disclosure is performed, without removing the substrate from the tool.

In some embodiments the metal or metallic surface comprises a conductive metal oxide, nitride, carbide, boride, or combination thereof. For example, the metal or metallic surface may comprise one or more of RuOₓ, NbCₓ, NbBₓ, NiOₓ, CoOₓ, NbOₓ, WNCₓ, TaN, or TiN.

In some embodiments the metal or metallic material of the metal or metallic surface is electrically conductive with or without surface oxidation. In some embodiments, the first surface comprises electrically conductive material. In some embodiments metal or a metallic surface comprises one or more transition metals. In some embodiments, the first surface consists essentially of, or consist of conductive material. By a conductive material is herein meant material that has electrical conductivity comparable to materials that are generally held to be conductive in the art of semiconductor device manufacture. In some embodiments, resistivity of a conductive material may vary from about 2 μOhm cm to about 5 mOhm cm.

In some embodiments, a metal surface may be doped with non-metal or semimetal elements to influence its electrical properties. In some embodiments, the first surface comprises a doped metal surface. In some embodiments, the first surface consists essentially of, or consists of doped metal surface.

The second surface may comprise a dielectric material. Examples of possible dielectric materials include silicon oxide-based materials, including grown or deposited silicon dioxide, doped and/or porous oxides, native oxide on silicon, etc. In some embodiments the dielectric material comprises a metal oxide. In some embodiments the dielectric material comprises a low k material.

In some embodiments, the second surface comprises dielectric material. In some embodiments, the second surface consists essentially of, or consists of dielectric material. In some embodiments, the dielectric material is silicon oxide, such as native oxide, thermal oxide or silicon oxycarbide. In some embodiments, the dielectric material is a metal oxide. In some embodiments, the dielectric material is a high k material. The high k material may maybe selected from a group consisting of HfO₂, ZrO₂, HfSiO₄, ZrSiO₄, Ta₂O₅, SiCN and SiN. In some embodiments, the dielectric material is a low k material, such as SiOC.

In some embodiments the second surface may comprise —OH groups. In some embodiments the second surface may be a SiO₂ surface or a SiO₂-based surface. In some embodiments the second surface may comprise Si—O bonds. In some embodiments the second surface may comprise a SiO₂ based low-k material. In some embodiments the second surface may comprise more than about 30%, preferably more than about 50% of SiO₂. In some embodiments the second surface may comprise GeO₂. In some embodiments the second surface may comprise Ge—O bonds. In some embodiments a transition metal-containing material is selectively deposited on a first metal or metallic surface relative to a second Si or Ge surface, for example an HF-dipped Si or HF-dipped Ge surface.

In certain embodiments the first surface may comprise a silicon dioxide surface and the second dielectric surface may comprise a second, different silicon dioxide surface. For example, in some embodiments the first surface may comprise a naturally or chemically grown silicon dioxide surface. In some embodiments the second surface may comprise a thermally grown silicon dioxide surface. In other embodiments, the second surface may be replaced with a deposited silicon oxide layer.

In an aspect, a semiconductor device structure comprising material deposited according to the method presented herein is disclosed. As used herein, a “structure” can be or include a substrate as described herein. Structures can include one or more layers overlying the substrate, such as one or more layers formed according to a method according to the current disclosure.

### Selectivity

By appropriately selecting the deposition conditions, transition metal-containing material may be selectively deposited on the first surface relative to the second surface. The methods according to the current disclosure may be performed without pre-treatments, such as passivation or other surface treatments to bring about selectivity. Thus, in some embodiments of the methods presented in the current disclosure, the deposition is inherently selective. However, as is understood by the skilled person, selectivity may be improved by processes such as cleaning of substrate surface, selective etching or the like.

Selectivity can be given as a percentage calculated by [(deposition on first surface)−(deposition on second surface)]/(deposition on the first surface). Deposition can be measured in any of a variety of ways. In some embodiments deposition may be given as the measured thickness of the deposited material. In some embodiments deposition may be given as the measured amount of material deposited.

In some embodiments, selectivity is greater than about 30%, greater than about 50%, greater than about 75%, greater than about 85%, greater than about 90%, greater than about 93%, greater than about 95%, greater than about 98%, greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments the transition metal-containing material deposited on the first surface of the substrate may have a thickness less than about 50 nm, less than about 20 nm, less than about 10 nm, less than about 5 nm, less than about 3 nm, less than about 2 nm, or less than about 1 nm, while a ratio of transition metal-containing material deposited on the first surface of the substrate relative to the second surface of the substrate may be greater than or equal to about 2:1, greater than or equal to about 20:1, greater than or equal to about 200:1, For example, ratio of transition metal-containing material deposited on the first surface of the substrate relative to the second surface of the substrate may be about 150:1, about 100:1, about 50:1, about 20:1, about 15:1, about 10:1, about 5:1, about 3:1, or about 2:1.

In some embodiments, selectivity of the selective deposition processes described herein may depend on the materials which comprise the first and/or second surface. For example, in some embodiments, where the first surface comprises a Cu surface and the second surface comprises a dioxide surface, the selectivity may be greater than about 10:1 or greater than about 20:1. In some embodiments, where the first surface comprises a metal or metal oxide and the second surface comprises a silicon dioxide surface, the selectivity may be greater than about 5:1.

### Vapor Deposition

A transition metal-containing material is deposited using a cyclic deposition process. As used herein, the term “cyclic deposition” may refer to the sequential introduction of precursors (reactants) into a reaction chamber to deposit a layer over a substrate, and it includes processing techniques such as atomic layer deposition (ALD) and cyclic chemical vapor position (cyclic CVD). CVD type processes typically involve gas phase reactions between two or more precursors. The precursors may be provided simultaneously to a reaction chamber containing a substrate on which material is to be deposited. The precursors may be provided in partially or completely separated pulses. The substrate and/or reaction chamber can be heated to promote the reaction between the gaseous precursors. In some embodiments the precursors are provided until a layer having a desired thickness is deposited. In some embodiments, cyclic CVD type processes can be used with multiple cycles to deposit a thin material having a desired thickness. In cyclic CVD-type processes, the precursors may be provided to the reaction chamber in pulses that do not overlap, or that partially or completely overlap.

ALD-type processes are based on controlled, typically self-limiting surface reactions of precursors. Vapor phase reactions are avoided by feeding the precursors alternately and sequentially into the reaction chamber. Vapor phase precursors are separated from each other in the reaction chamber, for example, by removing excess precursors and/or reaction by-products from the reaction chamber between precursor pulses. This may be accomplished with an evacuation step and/or with an inert gas pulse or purge. In some embodiments the substrate is contacted with a purge gas, such as an inert gas. For example, the substrate may be contacted with a purge gas between precursor pulses to remove excess precursor and reaction by-products.

In some embodiments each reaction is self-limiting and monolayer by monolayer growth is achieved. These may be referred to as “true ALD” reactions. In some such embodiments the transition metal precursor may adsorb on the substrate surface in a self-limiting manner. A second precursor may react in turn with the adsorbed transition metal precursor to form transition metal-containing material on the substrate. In some embodiments, up to a monolayer of transition metal-containing material may be formed in in one deposition cycle. A reducing agent may be introduced to reduce a transition metal into elemental transition metal.

In some embodiments, a deposition process for transition metal-containing material has one or more phases which are not self-limiting. For example, in some embodiments at least one of the precursors may be at least partially decomposed on the substrate surface. Thus, in some embodiments the process may operate in a process condition regime close to CVD conditions or in some cases fully in CVD conditions.

The method according to the current disclosure may also be used in a spatial atomic layer deposition apparatus. In spatial ALD, the precursors are supplied continuously in different physical sections and the substrate is moving between the sections. There may be provided at least two sections where, in the presence of a substrate, a half-reaction can take place. If the substrate is present in such a half-reaction section a monolayer may form from the first or second precursor. Then, the substrate is moved to the second half-reaction zone, where the ALD cycle is completed with the first or second precursor to form the target material. Alternatively, the substrate position could be stationary and the gas supplies could be moved, or some combination of the two. To obtain thicker layers, this sequence may be repeated.

Purging means that vapor phase precursors and/or vapor phase byproducts are removed from the substrate surface such as by evacuating the reaction chamber with a vacuum pump and/or by replacing the gas inside a reaction chamber with an inert gas such as argon or nitrogen. Purging may be performed between two precursor pulses. Typical purging times are from about 0.05 to 20 seconds, and can be about 0.2 and 10, or between about 0.5 and 5 seconds. However, other purge times can be utilized if necessary, such as where highly conformal step coverage over extremely high aspect ratio structures or other structures with complex surface morphology is needed, or where different reactor types may be used, such as a batch reactor. As described above for ALD, purging may be performed in a temporal or in a spatial mode.

In this disclosure, “gas” can include material that is a gas at normal temperature and pressure (NTP), a vaporized solid and/or a vaporized liquid, and can be constituted by a single gas or a mixture of gases, depending on the context. The term “inert gas” can refer to a gas that does not take part in a chemical reaction to an appreciable extent. Exemplary inert gases include He and Ar and any combination thereof. In some cases, nitrogen and/or hydrogen can be an inert gas. A gas other than the process gas, i.e., a gas introduced without passing through a gas distribution assembly, other gas distribution device, or the like, can be used for, e.g., sealing the reaction space, and can include a seal gas, such as a rare gas.

The term “precursor” can refer to a compound that participates in the chemical reaction that produces another compound, and particularly to a compound that constitutes deposited material. The term “reactant” can be used interchangeably with the term precursor. However, a reactant may be used for chemistries that modify deposited material. For example, a reducing agent reducing a transition metal to an elemental metal may be called a reactant.

In some embodiments, the method according to the current disclosure is a thermal deposition method. A thermal deposition method is to be understood as a method, in which no transition metal precursor or second precursor activation by plasma. However, In some embodiments, the method may comprise one or more plasma activation steps. Such processes may be termed plasma processes, although they may include thermal deposition steps as well.

### Deposited Material

Transition metal-containing material may be deposited by the methods according to the current disclosure. In some embodiments, the transition metal is a first-row transition metal. In other words, the transition metal is selected from a group consisting of scandium (Sc), titanium (Ti), vanadium (V), chromium (Cr), manganese (Mn), iron (Fe), cobalt (Co), nickel (Ni), copper (Cu) and zinc (Zn). In some embodiments, the transition metal is manganese. In some embodiments, the transition metal may be selected from a group consisting of manganese, iron, cobalt, nickel and copper. In some embodiments, the transition metal may be selected from a group consisting of cobalt, nickel and copper. In some embodiments, the transition metal is iron. In some embodiments, the transition metal is cobalt. In some embodiments, the transition metal is nickel. In some embodiments, the transition metal is copper. The transition metal-containing material may contain one or more transition metals.

The transition metal-containing material may contain a second element. The transition metal-containing material may comprise a transition metal oxide. In some embodiments, the transition metal-containing material may comprise oxygen in another form than oxide. The transition metal-containing material may comprise a transition metal nitride. In some embodiments, the transition metal-containing material may comprise nitrogen in another form than nitride. The transition metal-containing material may comprise a transition metal sulfide. In some embodiments, the transition metal-containing material may comprise sulfur in another form than sulfide. The transition metal-containing material may comprise a transition metal silicide. The transition metal-containing material may comprise a transition metal phosphide. The transition metal-containing material may comprise a transition metal selenide. The transition metal-containing material may comprise a transition metal boride.

In some embodiments, cyclic deposition methods may be utilized to selectively deposit cobalt-containing layers, such as, for example, elemental cobalt, cobalt oxides, cobalt nitrides, cobalt silicides, cobalt phosphides, cobalt selenides, cobalt sulfides or cobalt borides.

In some embodiments, cyclic deposition methods may be utilized to selectively deposit nickel-containing layers, such as, for example, elemental nickel, nickel oxides, nickel nitrides, nickel silicides, nickel phosphides, nickel selenides, nickel sulfides or nickel borides.

In some embodiments, cyclic deposition methods may be utilized to selectively deposit copper-containing layers, such as, for example, elemental copper, copper oxides, copper nitrides, copper silicides, copper phosphides, copper selenides, copper sulfides or copper borides.

In some embodiments, cyclic deposition methods may be utilized to selectively deposit manganese-containing layers, such as, for example, elemental manganese, manganese oxides, manganese nitrides, manganese silicides, manganese phosphides, manganese selenides, manganese sulfides or manganese borides.

In some embodiments, cyclic deposition methods may be utilized to selectively deposit iron-containing layers, such as, for example, elemental iron, iron oxides, iron nitrides, iron silicides, iron phosphides, iron selenides, iron sulfides or iron borides.

In some embodiments, a transition metal-containing material may comprise, for example, from about 70 to about 99.5 at. % transition metal-containing material, or from about 80 to about 99.5 at. % transition metal-containing material, or from about 90 to about 99.5 at. % transition metal-containing material. A transition metal-containing material deposited by a method according to the current disclosure may comprise, for example about 80 at. %, about 83 at. %, about 85 at. %, about 87 at. %, about 90 at. %, about 95 at. %, about 97 at. % or about 99 at. % transition metal-containing material. In some embodiments, the transition metal-containing material deposited according to the current disclosure comprises less than about 3 at. %, or less that about 1 at. % chlorine. In some embodiments, the transition metal-containing material deposited according to the current disclosure comprises less than about 2 at. %, less than about 1 at. %, or less that about 0.5 at. % oxygen. In some embodiments, the transition metal-containing material deposited according to the current disclosure comprises less than about 5 at. %, or less that about 2 at. %, or less that about 1 at. %, or less that about 0.5 at. % carbon. In some embodiments, the transition metal-containing material deposited according to the current disclosure comprises less than about 0.5 at. %, or less that about 0.2 at. %, or less that about 0.1 at. % nitrogen. In some embodiments, the transition metal-containing material deposited according to the current disclosure comprises less than about 1.5 at. %, or less that about 1 at. % hydrogen.

In some embodiments, the transition metal-containing material consists essentially of, or consists of, transition metal-containing material. In some embodiments, the transition metal-containing material consist essentially of, or consist of, cobalt sulfide. In some embodiments, the transition metal-containing material consist essentially of, or consist of, nickel sulfide. In some embodiments, the transition metal-containing material consist essentially of, or consist of, copper sulfide. In some embodiments, the transition metal-containing material consist essentially of, or consist of, cobalt selenide. In some embodiments, the transition metal-containing material consist essentially of, or consist of, nickel selenide. In some embodiments, the transition metal-containing material consist essentially of, or consist of, copper selenide. In some embodiments, the transition metal-containing material consist essentially of, or consist of, cobalt telluride. In some embodiments, the transition metal-containing material consist essentially of, or consist of, nickel telluride. In some embodiments, the transition metal-containing material consist essentially of, or consist of, copper telluride.

In some embodiments, transition metal-containing material deposited according to the current disclosure may form a layer. As used herein, the term “layer” and/or “film” can refer to any continuous or non-continuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a non-continuous layer serving to increase the rate of nucleation of another material. However, the seed layer may also be substantially or completely continuous.

### Transition Metal Precursors

In some embodiments, transition metal-containing material or a transition metal-containing layer may be deposited by a cyclic deposition process using a transition metal precursor comprising a transition metal halide compound. In some embodiments, transition metal-containing material or a transition metal-containing layer may be deposited by a cyclic deposition process using a transition metal precursor, wherein a transition metal compound comprises an adduct-forming ligand.

In some embodiments, the transition metal precursor may comprise a transition metal compound with an adduct-forming ligand, such as monodentate, bidentate, or multidentate adduct-forming ligand. In some embodiments, the transition metal precursor may comprise a transition metal halide compound with adduct-forming ligand, such as monodentate, bidentate, or multidentate adduct-forming ligand. In some embodiments, the transition metal precursor may comprise a transition metal compound with adduct-forming ligand comprising nitrogen, such as monodentate, bidentate, or multidentate adduct-forming ligand comprising nitrogen. In some embodiments, the adduct-forming ligand comprises at least one of nitrogen, phosphorous, oxygen or sulfur.

In some embodiments, the transition metal in the transition metal halide compound is selected from a group consisting of manganese, iron, cobalt, nickel and copper.

In some embodiments, the transition metal halide compound comprises a transition metal chloride or a transition metal iodide or a transition metal fluoride. Specifically, the transition metal halide compound may comprise at least one of a cobalt chloride, a nickel chloride, or a copper chloride, cobalt bromide, a nickel bromide, or a copper bromide, cobalt iodide, a nickel iodide, or a copper iodide.

In some embodiments, the transition metal precursor may comprise a transition metal compound with adduct-forming ligand comprising phosphorous, oxygen, or sulfur, such as monodentate, bidentate, or multidentate adduct-forming ligand comprising phosphorous, oxygen or sulfur. For example, in some embodiments, the transition metal halide compound may comprise a transition metal chloride, a transition metal iodide, a transition metal fluoride, or a transition metal bromide. In some embodiments of the disclosure, the transition metal halide compound may comprise a transition metal species, including, but not limited to, at least one of manganese, iron, cobalt, nickel, or copper. In some embodiments of the disclosure, the transition metal halide compound may comprise at least one of a manganese chloride, an iron chloride, a cobalt chloride, a nickel chloride, or a copper chloride. In some embodiments of the disclosure, the transition metal halide compound may comprise at least one of a manganese bromide, an iron bromide, a cobalt bromide, a nickel bromide, ora copper bromide. In some embodiments of the disclosure, the transition metal halide compound may comprise at least one of a manganese fluoride, an iron fluoride, a cobalt fluoride, a nickel fluoride, or a copper fluoride. In some embodiments, the transition metal halide compound comprises a bidentate nitrogen-containing ligand. In some embodiments, the transition metal halide compound may comprise a bidentate nitrogen-containing adduct-forming ligand. In some embodiment, the transition metal halide compound may comprise an adduct-forming ligand including two nitrogen atoms, wherein each of the nitrogen atoms are bonded to at least one carbon atom. In some embodiments of the disclosure, the transition metal halide compound comprises one or more nitrogen atoms bonded to a central transition metal atom thereby forming a metal complex.

In some embodiments, the bidentate nitrogen containing adduct-forming ligand comprises two nitrogen atoms, each of nitrogen atoms bonded to at least one carbon atom.

In some embodiments of the disclosure, the transition metal precursor may comprise a transition metal compound having the formula (I):

(adduct)ₙ-M-Xₐ (I)

wherein each of the “adducts” is an adduct-forming ligand and can be independently selected to be a mono-, a bi-, or a multidentate adduct-forming ligand or mixtures thereof: n is from 1 to 4 in case of monodentate forming ligand, n is from 1 to 2 in case of bi- or multidentate adduct-forming ligand; M is a transition metal, such as, for example, cobalt (Co), copper (Cu), or nickel (Ni); wherein each of Xₐ is another ligand, and can be independently selected to be a halide or other ligand; wherein a is from 1 to 4, and some instances a is 2.

In some embodiments of the disclosure, the adduct-forming ligand in the transition metal compound, such as a transition metal halide compound, may comprise a monodentate, bidentate, or multidentate adduct-forming ligand which coordinates to the transition metal atom, of the transition metal compound, through at least one of a nitrogen atom, a phosphorous atom, an oxygen atom, or a sulfur atom. In some embodiments of the disclosure, the adduct-forming ligand in the transition metal compound may comprise a cyclic adduct-forming ligand. In some embodiments of the disclosure, the adduct-forming ligand in the transition metal compound may comprise mono, di-, or polyamines. In some embodiments of the disclosure, the adduct-forming ligand in the transition metal compound may comprise mono-, di-, or polyethers. In some embodiments, the adduct-forming ligand in the transition metal compound may comprise mono-, di-, or polyphosphines. Phosphines may have advantages especially in embodiments, in which the transition metal comprises copper. In some embodiments, the adduct-forming ligand in the transition metal compound may comprise carbon and/or in addition to the nitrogen, oxygen, phosphorous, or sulfur in the adduct-forming ligand.

In some embodiments, the adduct-forming ligand in the transition metal compound may comprise one monodentate adduct-forming ligand. In some embodiments of the disclosure, the adduct-forming ligand in the transition metal compound may comprise two monodentate adduct-forming ligands. In some embodiments of the disclosure, the adduct-forming ligand in the transition metal compound may comprise three monodentate adduct-forming ligands. In some embodiments of the disclosure, the adduct-forming ligand in the transition metal compound may comprise four monodentate adduct-forming ligands. In some embodiments of the disclosure, the adduct-forming ligand in the transition metal compound may comprise one bidentate adduct-forming ligand. In some embodiments of the disclosure, the adduct-forming ligand in the transition metal compound may comprise two bidentate adduct-forming ligands. In some embodiments of the disclosure, the adduct-forming ligand in the transition metal compound may comprise one multidentate adduct-forming ligand. In some embodiments of the disclosure, the adduct-forming ligand in the transition metal compound may comprise two multidentate adduct-forming ligands.

In some embodiments, the adduct-forming ligand comprises nitrogen, such as an amine, a diamine, or a polyamine adduct-forming ligand. In such embodiments, the transition metal compound may comprise at least one of, triethylamine (TEA), N,N,N′,N′-tetramethyl-1,2-ethylenediamine (CAS: 110-18-9, TMEDA), N,N,N′,N′-tetraethylethylenediamine (CAS: 150-77-6, TEEDA), N,N′-diethyl-1,2-ethylenediamine (CAS: 111-74-0, DEEDA), N,N′-diisopropylethylenediamine (CAS: 4013-94-9), N,N,N′,N′-tetramethyl-1,3-propanediamine (CAS: 110-95-2, TMPDA), N,N,N′,N′-tetramethylmethanediamine (CAS: 51-80-9, TMM DA), N,N,N′,N″,N″-pentamethyldiethylenetriamine (CAS: 3030-47-5, PMDETA), diethylenetriamine (CAS: 111-40-0, DIEN), triethylenetetraamine (CAS: 112-24-3, TRIEN), tris(2-aminoethyl)amine (CAS: 4097-89-6, TREN, TAEA), 1,1,4,7,10,10-hexamethyltriethylenetetramine (CAS: 3083-10-1, HMTETA), 1,4,8,11-tetraazacyclotetradecane (CAS: 295-37-4, Cyclam), 1,4,7-Trimethyl-1,4,7-triazacyclononane (CAS: 96556-05-7), or 1,4,8,11-tetramethyl-1,4,8,11-tetraazacyclotetradecane (CAS: 41203-22-9). In some embodiments, the adduct-forming ligand comprises TMEDA or TMPDA.

In some embodiments, the adduct-forming ligand comprises phosphorous, such as a phosphine, a diphosphine, or a polyphosphine adduct-forming ligand. For example, the transition metal compound may comprise at least one of triethylphosphine (CAS: 554-70-1), trimethyl phosphite (CAS: 121-45-9), 1,2-bis(diethylphosphino)ethane (CAS: 6411-21-8, BDEPE), or 1,3-bis(diethylphosphino) ropane (CAS: 29149-93-7).

In some embodiments of the disclosure, the adduct-forming ligand comprises oxygen, such as an ether, a diether, or a polyether adduct-forming ligand. For example, the transition metal compound may comprise at least one of, 1,4-dioxane (CAS: 123-91-1), 1,2-dimethoxyethane (CAS: 110-71-4, DME, monoglyme), diethylene glycol dimethyl ether (CAS: 111-96-6, diglyme), triethylene glycol dimethyl ether (CAS: 112-49-2, triglyme), or 1,4,7,10-tetraoxacyclododecane (CAS: 294-93-9, 12-Crown-4).

In some embodiments, the adduct-forming ligand may comprise a thioether, or mixed ether amine, such as, for example, at least one of 1,7-diaza-12-crown-4: 1,7-dioxa-4,10-diazacyclododecane (CAS: 294-92-8), or 1,2-bis(methylthio)ethane (CAS: 6628-18-8).

In some embodiments, the transition metal halide compound may comprise cobalt chloride N,N,N′,N′-tetramethyl-1,2-ethylenediamine (CoCl₂(TMEDA)). In some embodiments, the transition metal halide compound may comprise cobalt bromide tetramethylethylenediamine (CoBr₂(TMEDA)). In some embodiments, the transition metal halide compound may comprise cobalt iodide tetramethylethylenediamine (CoI₂(TMEDA)). In some embodiments, the transition metal halide compound may comprise cobalt chloride N,N,N′,N′-tetramethyl-1,3-propanediamine (CoCl₂(TMPDA)). In some embodiments, the transition metal halide compound may comprise at least one of cobalt chloride N,N,N′,N′-tetramethyl-1,2-ethylenediamine (CoCl₂(TMEDA)), nickel chloride tetramethyl-1,3-propanediamine (NiCl₂(TMPDA)), or nickel iodide tetramethyl-1,3-propanediamine (NiI₂(TMPDA)). In some embodiments, the transition metal compound or the transition metal halide compound comprises at least one of CoCl₂(TMEDA), CoBr₂(TMEDA), CoI₂(TMEDA), CoCl₂(TMPDA), or NiCl₂(TMPDA).

In some embodiments of the disclosure, contacting the substrate with a transition metal precursor may comprise providing the transition metal precursor in the reaction chamber for a time period of between about 0.01 seconds and about 60 seconds, between about 0.05 second sand about 10 seconds, between about 0.1 seconds and about 5.0 seconds, between about 0.5 seconds and about 10 seconds, between about 1 second and about 30 seconds. For example, the transition metal precursor may be provided in the reaction chamber for about 0.5 seconds, for about 1 second, for about 1.5 seconds, for about 2 seconds or for about 3 seconds. In addition, during the pulsing of the transition metal precursors, the flow rate of the transition metal precursor may be less than 2000 sccm, or less than 500 sccm, or even less than 100 sccm. In addition, during providing the transition metal precursor over the substrate the now rate of the transition metal precursor may range from about 1 to 2000 sccm, from about 5 to 1000 sccm, or from about 10 to about 500 sccm.

Excess transition metal precursor and reaction byproducts (if any) may be removed from the surface, e.g., by pumping with an inert gas. For example, in some embodiments of the disclosure, the methods may comprise a purge cycle wherein the substrate surface is purged for a time period of less than approximately 2 seconds. Excess transition metal precursor and any reaction byproducts may be removed with the aid of a vacuum, generated by a pumping system, in fluid communication with the reaction chamber.

In some embodiments, a transition metal halide compound comprises a bidentate nitrogen-containing ligand. In some embodiments, the bidentate nitrogen-containing ligand comprises a bidentate nitrogen containing adduct-forming ligand.

### Second Precursor

The transition metal precursor may comprise a transition metal halide compound and a second precursor may comprise at least one of an oxygen precursor, a nitrogen precursor, a silicon precursor, a sulfur precursor, a selenium precursor, a phosphorous precursor, a boron precursor, or a reducing agent. The selection of the second precursor will be done according to the type of material to be deposited. For a transition metal oxide material, an oxygen precursor may be selected. For a transition metal nitride material, a nitrogen precursor may be selected. For a transition metal silicide material, a silicon precursor may be selected. For a transition metal sulfide material, a sulfur precursor may be selected. For a transition metal selenide material, a selenium precursor may be selected. For a transition metal phosphide material, a phosphorus precursor may be selected. For a transition metal boride material, a boron precursor may be selected. For an elemental transition metal material, a reducing agent may be selected.

In some embodiments of the disclosure each deposition cycle comprises two distinct deposition phases. In a first phase of a deposition cycle (“the metal phase”), the substrate is contacted with a first vapor phase reactant comprising a metal precursor by providing a transition metal precursor in a reaction chamber. The transition metal precursor adsorbs onto the substrate surface. The term adsorption is intended to be non-limiting in respect of a specific mode of interaction between the precursor and the substrate. Without limiting the current disclosure to any specific theory of molecular interaction, in some embodiments, the transition metal precursor may chemisorb on the substrate surface.

In a second phase of deposition, the substrate is contacted with a second precursor by providing a second precursor in the reaction chamber. The second precursor may comprise at least one of an oxygen precursor, a nitrogen precursor, a silicon precursor, a sulfur precursor, a selenium precursor, a phosphorous precursor, a boron precursor, or a reducing agent. The second precursor may react with transition metal species on a surface of the substrate to form a transition metal-containing material on the substrate, such as, for example, an elemental transition metal, a transition metal oxide, a transition metal nitride, a transition metal silicide, a transition metal selenide, a transition metal phosphide, a transition metal boride, and mixtures thereof, as well transition metal containing materials further comprising carbon and/or hydrogen.

In some embodiments, the second precursor comprises an oxygen precursor. In some embodiments, the oxygen precursor is selected from a group consisting of ozone (O₃), molecular oxygen (O₂), oxygen atoms (O), an oxygen plasma, oxygen radicals, oxygen excited species, water (H₂O), and hydrogen peroxide (H₂O₂). In some embodiments, the transition metal-containing material comprises a transition metal oxide. In some embodiments, the transition metal oxide comprises, consist essentially of, or consist of cobalt (II) oxide (CoO).

In some embodiments, the second precursor comprises a nitrogen precursor. In some embodiments, the nitrogen precursor comprises an N—H bond. The nitrogen precursor may comprise at least one of ammonia (NH₃), ammonia plasma, hydrazine (N₂H₄), triazane (N₃H₅), hydrazine derivatives, tert-butylhydrazine (C₄H₉N₂H₃), methylhydrazine (CH₃NHNH₂), dimethylhydrazine ((CH₃)₂N₂H₂), or a nitrogen plasma or nitrogen plasma comprising hydrogen.

In some embodiments, the transition metal-containing material comprises a transition metal nitride. However, In some embodiments, the transition metal-containing material may comprise transition metal and nitrogen, but the material may, at least to some extent, be another material than transition metal nitride. For example, the transition metal-comprising material may be a nitrogen-doped transition metal.

In some embodiments, the second precursor may comprise a hydrocarbon substituted hydrazine precursor. In a second phase of the deposition cycle, the substrate may be contacted with a second precursor comprising a hydrocarbon substituted hydrazine precursor. In some embodiments, methods according to the current disclosure may further comprise selecting the substituted hydrazine to comprise an alkyl group with at least four (4) carbon atoms. In the current disclosure, “alkyl group” refers to a saturated or unsaturated hydrocarbon chain of at least four (4) carbon atoms in length, such as, but not limited to, butyl, pentyl, hexyl, heptyl and octyl and isomers thereof, such as n-, iso-, sec- and tert-isomers of those. The alkyl group may be straight chain or branched-chain and may embrace all structural isomer forms of the alkyl group. In some embodiments the alkyl chain might be substituted. In some embodiments, the alkyl-hydrazine may comprise at least one hydrogen bonded to nitrogen. In some embodiments, the alkyl-hydrazine may comprise at least two hydrogens bonded to nitrogen. In some embodiments, the alkyl-hydrazine may comprise at least one hydrogen bonded to nitrogen and at least one alkyl chain bonded to nitrogen. In some embodiments, the second precursor may comprise an alkylhydrazine and may further comprise one or more of tert-butylhydrazine (TBH, C₄H₉N₂H₃), dimethylhydrazine or diethylhydrazine. In some embodiments, the substituted hydrazine has at least one hydrocarbon group attached to nitrogen. In some embodiments, the substituted hydrazine has at least two hydrocarbon groups attached to nitrogen. In some embodiments, the substituted hydrazine has at least three hydrocarbon groups attached to nitrogen. In some embodiments, the substituted hydrazine has at least one C1-C3 hydrocarbon group attached to nitrogen. In some embodiments, the substituted hydrazine has at least one C4-C10 hydrocarbon group attached to nitrogen. In some embodiments, the substituted hydrazine has linear, branched or cyclic or aromatic hydrocarbon group attached to nitrogen. In some embodiments, the substituted hydrazine comprises substituted hydrocarbon group attached to nitrogen.

In some embodiments, the substituted hydrazine has the following formula (II):

R^{I}R^{II}—N—NR^{III}R^{IV}, (II)

wherein R^{I} can be selected from hydrocarbon group, such as linear, branched, cyclic, aromatic or substituted hydrocarbon group and each of the R^{II}, R^{III}, R^{IV} groups can be independently selected to be hydrogen or hydrocarbon groups, such as linear, branched, cyclic, aromatic or substituted hydrocarbon group.

In some embodiments in the formula (II) each of the R^{I}, R^{II}, R^{III}, R^{IV} can be C1-C10 hydrocarbon, C1-C3 hydrocarbon, C4-C10 hydrocarbon or hydrogen, such as linear, branched, cyclic, aromatic or substituted hydrocarbon group. In some embodiments, at least one of the R^{I}, R^{II}, R^{III}, R^{IV} groups comprises aromatic group such as phenyl group. In some embodiments, at least one of the R^{I}, R^{II}, R^{III}, R^{IV} groups comprises methyl, ethyl, n-propyl, i-propyl, n-butyl, i-butyl, s-butyl, tert-butyl group or phenyl group. In some embodiments, at least two of the each R^{I}, R^{II}, R^{III}, R^{IV} groups can be independently selected to comprise methyl, ethyl, n-propyl, i-propyl, n-butyl, i-butyl, s-butyl, tert-butyl group or phenyl group. In some embodiments R^{II}, R^{III} and R^{IV} groups are hydrogen. In some embodiments, at least two one of the R^{II}, R^{III} and R^{IV} groups are hydrogen. In some embodiments, at least one of the R^{II}, R^{III} and R^{IV} groups are hydrogen. In some embodiments all of the R^{II}, R^{III} and R^{IV} groups are hydrocarbons.

In embodiments, in which the second precursor comprises a silicon precursor, the silicon precursor may comprise at least one of silane (SiH₄), disilane (Si₂H₆), trisilane (Si₃H₈), tetrasilane (Si₄H₁₀), isopentasilane (Si₅H₁₂), or neopentasilane (Si₅H₁₂). In embodiments, in which the second precursor comprises a silicon precursor, the silicon precursor may comprise a C1-C4 alkylsilane. In embodiments of the disclosure Wherein the second precursor comprises a silicon precursor, the silicon precursor may comprise a precursor from silane family.

In embodiments in which the second precursor comprises a boron precursor, the boron precursor may comprise at least one of borane (BH₃), diborane (B₂H₆) or other boranes, such as decaborane (B₁₀H₁₄).

In embodiments in which the second precursor comprises a hydrogen precursor, the hydrogen precursor may comprise at least one of Hz, H atoms, H-ions, H-plasma or H-radicals.

In some embodiments, the second precursor comprises a phosphorus precursor, a sulfur precursor, or a selenide precursor. In some embodiments the sulfur precursor comprises hydrogen and sulfur. In some embodiments the sulfur precursor is an alkylsulfur compound. In some embodiments the second precursor comprises one or more of elemental sulfur, H₂S, (CH₃)₂S, (NH₄)₂S, ((CH₃)₂SO), and H₂S₂. In some embodiments, the selenium precursor is an alkylselenium compound. In some embodiments the second precursor comprises one or more of elemental selenium, H₂Se, (CH₃)₂Se and H₂Se₂. In some embodiments, the selenium precursor comprises hydrogen and selenium. In some embodiments, the second precursor may comprise alkylsilyl compounds of Te, Sb, Se, such as (Me₃Si)₂Te, (Me₃Si)₂Se or (Me₃Si)₃Sb, wherein Me stands for methyl. In some embodiments, the phosphorus precursor is an alkylphosphorus compound. In some embodiments the second precursor comprises one or more of elemental phosphorus, PH₃ or alkylphosphines, such as methylphoshpine. In some embodiments the phosphorus precursor comprises hydrogen and phosphorus.

In embodiments in which the second precursor comprises an organic precursor, such as a reducing agent, for example, alcohols, aldehydes or carboxylic acids or other organic compounds may be utilized. For example organic compounds not having metals or semimetals, but comprising —OH group. Alcohols can be primary alcohols, secondary alcohols, tertiary alcohols, polyhydroxy alcohols, cyclic alcohols, aromatic alcohols, and other derivatives of alcohols.

Primary alcohols have an —OH group attached to a carbon atom which is bonded to another carbon atom, in particular primary alcohols according to the general formula (III):

R₁—OH (III)

wherein R1 is a linear or branched C1-C20 alkyl or alkenyl group, such as methyl, ethyl, propyl, butyl, pentyl or hexyl. Examples of primary alcohols include methanol, ethanol, propanol, butanol, 2-methyl propanol and 2-methyl butanol.

Secondary alcohols have an —OH group attached to a carbon atom that is bonded to two other carbon atoms. In particular, secondary alcohols have the general formula (IV):

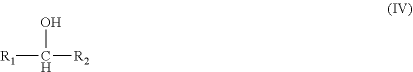

wherein R₁ and R₂ are selected independently from the group of linear or branched C1-C20 alkyl and alkenyl groups, such as methyl, ethyl, propyl, butyl, pentyl or hexyl. Examples of secondary alcohols include 2-propanol and 2-butanol.

Tertiary alcohols have an —OH group attached to a carbon atom that is bonded to three other carbon atoms. In particular, tertiary alcohols have the general formula (V):

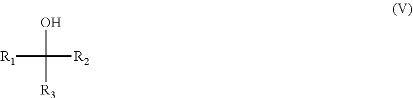

Wherein R₁, R₂ and R₃ are selected independently from the group of linear or branched C1-C20 alkyl and alkenyl groups, such as methyl, ethyl, propyl, butyl, pentyl or hexyl. An example of a tertiary alcohol is tert-butanol.

Polyhydroxy alcohols, such as diols and triols, have primary, secondary and/or tertiary alcohol groups as described above. Examples of polyhydroxy alcohol are ethylene glycol and glycerol.

Cyclic alcohols have an —OH group attached to at least one carbon atom which is part of a ring of 1 to 10, such as 5-6 carbon atoms.

Aromatic alcohols have at least one —OH group attached either to a benzene ring or to a carbon atom in a side chain.

Organic precursors may comprise at least one aldehyde group (—CHO) are selected from the group consisting of compounds having the general formula (VI), alkanedial compounds having the general formula (VII), halogenated aldehydes and other derivatives of aldehydes.

Thus, in one embodiment organic precursors are aldehydes having the general formula (VI):

R₁—CHO, (VI)

wherein R₁ is selected from the group consisting of hydrogen and linear or branched C1-C20 alkyl and alkenyl groups, such as methyl, ethyl, propyl, butyl, pentyl or hexyl. In some embodiments, R₁ is selected from the group consisting of methyl or ethyl. Exemplary compounds, but not limited to, according to formula (VI) are formaldehyde, acetaldehyde and butyraldehyde.

In some embodiments, organic precursors are aldehydes having the general formula (VII):

OHC—R₁—CHO, (VII)

wherein R₁ is a linear or branched C1-C20 saturated or unsaturated hydrocarbon. Alternatively, the aldehyde groups may be directly bonded to each other (R₁ is null).

Organic precursors containing at least one —COOH group can be selected from the group consisting of compounds of the general formula (VIII), polycarboxylic acids, halogenated carboxylic acids and other derivatives of carboxylic acids.

Thus, in one embodiment organic precursors are carboxylic acids having the general formula (VIII):

R₁—COOH (VIII)

Wherein R₁ is hydrogen or linear or branched C1-C20 alkyl or alkenyl group, such as methyl, ethyl, propyl, butyl, pentyl or hexyl, for example methyl or ethyl. In some embodiments, R₁ is a linear or branched C1-C3 alkyl or alkenyl group. Examples of compounds according to formula (VII) are formic acid, propanoic acid and acetic acid, in some embodiments formic acid (HCOOH).

In some embodiments, trimethyl aluminum may be used as a second precursor to deposit carbon-containing transition metal-containing materials. The carbon content of such materials may vary from about 20 at. % to about 60 at. %. Further, TBGeH (tributylgermanium hydride), as well as TBTH (tributyltin hydride) may be used to selectively deposit transition metal-containing layers according to the current disclosure.

In some embodiments, the second precursor may be a carbonyl group-containing precursor. In some embodiments, the second precursor may be a hydroxyl group-containing organic precursor.

In some embodiments, exposing, i.e., contacting, the substrate to the second precursor comprises pulsing the second precursor over the substrate for a time period of between 0.1 seconds and 2 seconds, or from about 0.01 seconds to about 10 seconds, or less than about 20 seconds, less than about 10 seconds or less than about 5 seconds. During the pulsing of the second precursor over the substrate the now rate of the second precursor may be less than 50 sccm, or less than 25 sccm, or less than 15 sccm, or even less than 10 sccm.

Excess second precursor and reaction byproducts, if any, may be removed from the substrate surface, for example, by a purging gas pulse and/or vacuum generated by a pumping system. Purging gas is preferably any inert gas, such as, without limitation, argon (Ar), nitrogen (N₂), helium (He), or in some instances hydrogen (H₂) could be used. A phase is generally considered to immediately follow another phase if a purge (i.e., purging gas pulse) or other precursor, reactant or by-product removal step intervenes.

A deposition cycle in which the substrate is alternatively contacted with the transition metal precursor (i.e., comprising the metal halide compound) and the second precursor by providing the precursor in the reaction chamber, may be repeated one or more times until a desired thickness of a transition metal-containing material is deposited. It should be appreciated that in some embodiments, the order of the contacting of the substrate with the transition metal precursor and the second precursor may be such that the substrate is first contacted with the second precursor followed by the transition metal precursor. In addition, in some embodiments, the cyclic deposition process may comprise contacting the substrate with the transition metal precursor one or more times prior to contacting the substrate with the second precursor one or more times and similarly may alternatively comprise contacting the substrate with the second precursor one or more times prior to contacting the substrate with the transition metal precursor one or more times.

In addition, some embodiments of the disclosure may comprise non-plasma precursors, e.g., the transition metal precursor and second precursors are substantially free of ionized reactive species. In some embodiments, the transition metal precursor and second precursors are substantially free of ionized reactive species, excited species or radical species. For example, both the transition metal precursor and the second precursor may comprise non-plasma precursors to prevent ionization damage to the underlying substrate and the associated defects thereby created. The use of non-plasma precursors may be especially useful when the underlying substrate contains fragile fabricated, or least partially fabricated, semiconductor device structures as the high energy plasma species may damage and/or deteriorate device performance characteristics.

### Reducing Agent

In some embodiments, cyclic deposition methods according to the current disclosure comprise an additional process step comprising, contacting the substrate with a reducing agent. The reducing agent may be provided in vapor phase in the reaction chamber. In some embodiments, the reducing agent may comprise at least one of hydrogen (H₂), a hydrogen (H₂) plasma, ammonia (NH₃), an ammonia (NH₃) plasma, hydrazine (N₂H₄), silane (SiH₄), disilane (Si₂H₆), trisilane (Si₃H₈), germane (GeH₄), digennane (Ge₂H₆), borane (BH₃), diborane (B₂H₆), tert-butyl hydrazine (TBH, C₄H₁₂N₂), a selenium precursor, a boron precursor, a phosphorous precursor, a sulfur precursor, an organic precursor (e.g., an alcohol, an aldehyde or a carboxylic acid, such as formic acid), aluminum hydride or a hydrogen precursor. In some embodiments, the method comprises contacting the substrate with a second precursor which is a reducing agent (without any additional precursor/reactant introducing steps).

In some embodiments, the method comprises further comprising contacting the substrate with a third precursor comprising a reducing agent precursor selected from the group consisting of tertiary butyl hydrazine (C₄H₁₂N₂), hydrogen (H₂), a hydrogen (H₂) plasma, ammonia (NH₃), an ammonia (NH₃) plasma, hydrazine (N₂H₄), silane (SiH₄), disilane (Si₂H₆), trisilane (Si₃H₈), germane (GeH₄), digermane (Ge₂H₆), borane (BH₃), and diborane (B₂H₆).

The reducing agent may be introduced into the reaction chamber and contact the substrate at various process stages in a cyclic deposition method according to the current disclosure. In some embodiments, the reducing agent may be provided in the reaction chamber and contact the substrate separately from the transition metal precursor and separately from the second precursor. For example, the reducing agent may be provided in the reaction chamber and contact the substrate prior to contacting the substrate with the transition metal precursor, after contacting the substrate with the transition metal precursor and prior to contacting the substrate with the second precursor, and/or after contacting the substrate with the second precursor. In some embodiments, the reducing agent may be introduced into the reaction chamber and contact the substrate simultaneously with the transition metal precursor and/or simultaneously with the second precursor. For example, the reducing agent and the transition metal precursor may be co-flowed into the reaction chamber and simultaneously contact the substrate, and/or the reducing agent and the second precursor may be co-flowed into the reaction chamber and simultaneously contact the substrate.

In some embodiments, the transition metal precursor may comprise a transition metal halide compound and the second precursor may comprise an oxygen precursor. In such embodiments, the cyclic deposition processes may deposit a transition metal oxide on the substrate. As a non-limiting example, the transition metal precursor may comprise CoCl₂(TMEDA), the second precursor may comprise water (H₂O), and the material deposited on the substrate may comprise a cobalt oxide. As a non-limiting example, the transition metal precursor may comprise CoCl₂(TMEDA), the second precursor may comprise TBH, and the material deposited on the substrate may comprise a nitrogen-doped cobalt. In some embodiments, the transition metal oxide may be further processed by exposing the transition metal oxide to a reducing agent. In some embodiments, the transition metal oxide may be exposed to at least one reducing agent comprising, forming gas (H₂+N₂), ammonia (NH₃), hydrazine (N₂H₄), molecular hydrogen (H₂), hydrogen atoms (H), a hydrogen plasma, hydrogen radicals, hydrogen excited species, alcohols, aldehydes, carboxylic acids, boranes or amines.

In some embodiments, exposing the transition metal oxide or the transition metal nitride to a reducing agent may reduce the transition metal oxide to an elemental transition metal. As a nonlimiting example, the cyclic deposition processes according to the current disclosure may be utilized to deposit a cobalt oxide material to a thickness of 50 nanometers (nm) and the cobalt oxide material may be exposed to 10% forming gas at a pressure of 1000 mbar and a temperature of approximately 250° C. to reduce the cobalt oxide material to elemental cobalt. In some embodiments, the transition metal oxide may have a thickness of less than 500 nm, or less than 100 nm, or less than 50 nm, or less than 25 nm, or less than 20 nm, or less than 10 nm, or less than 5 nm. In some embodiments, the transition metal oxide may be exposed to a reducing agent for less than 5 hours, or less than 1 hour, or less than 30 minutes, or less than 15 minutes, or less than 10 minutes, or less than 5 minutes, or even less than 1 minutes. In some embodiments, the transition metal oxide may be exposed to the reducing agent at a substrate temperature of less than 500° C., or less than 400° C., or less than 300° C., or less than 250° C., or less than 200° C., or even less than 150° C. In some embodiments, the transition metal oxide may be exposed to the reducing agent in a reduced pressure atmosphere, wherein the pressure may be from about 0.001 mbar to about 10 bar, or from about 1 mbar to about 1000 mbar.

The cyclic deposition processes described herein, utilizing a transition metal precursor comprising a transition metal halide compound and a second precursor to deposit a transition metal containing material, may be performed in an ALD or CVD deposition system with a heated substrate. For example, in some embodiments, methods may comprise heating the substrate to temperature of between approximately 80° C. and approximately 150° C., or even heating the substrate to a temperature of between approximately 80° C. and approximately 120° C. Of course, the appropriate temperature window for any given cyclic deposition process, such as, for an ALD reaction, will depend upon the surface termination and precursor species involved. Here, the temperature varies depending on the precursors being used and is generally at or below about 700° C. In some embodiments, the deposition temperature is generally at or above about 100° C. for vapor deposition processes, in some embodiments the deposition temperature is between about 100° C. and about 300° C., and in some embodiments the deposition temperature is between about 120° C. and about 200° C. In some embodiments the deposition temperature is less than about 500° C., or less than below about 400° C., or less than about 350° C., or below about 300° C. In some instances the deposition temperature can be below about 300° C., below about 200° C. or below about 100° C. In some instances the deposition temperature can be above about 20° C., above about 50° C. and above about 75° C. In some embodiments, the deposition temperature i.e., the temperature of the substrate during deposition is approximately 275° C.

In some embodiments, the growth rate of the transition metal containing material is from about 0.005 A/cycle to about 5 A/cycle, from about 0.01 A/cycle to about 2.0 A/cycle. In some embodiments the growth rate of the transition metal containing material is more than about 0.05 A/cycle, more than about 0.1 A/cycle, more than about 0.15 A/cycle, more than about 0.20 A/cycle, more than about 0.25 A/cycle, or more than about 0.3 A/cycle. In some embodiments the growth rate of the transition metal containing material is less than about 2.0 A/cycle, less than about 1.0 A/cycle, less than about 0.75 A/cycle, less than about 0.5 A/cycle, or less than about 0.2 A/cycle. In some embodiments, the growth rate of the transition metal containing material may be approximately 0.4 A/cycle.

### Cleaning Substrate Surface

In some embodiments, the method comprises cleaning the substrate before providing the transition metal precursor in the reaction chamber. In some embodiments, cleaning the substrate comprises contacting the substrate with a cleaning agent. In some embodiments, the cleaning agent comprises a chemical selected from beta-diketonates, cyclopentadienyl-containing chemicals, carbonyl-containing chemicals, carboxylic acids and hydrogen.

Thus, various cleaning agents may be suitable. For example, the cleaning agent may comprise a beta-diketonate. Examples of a beta-diketonate cleaning agents are hexafluoroacetylacetone (Hfac), acetylacetone (Hacac), or dipivaloylmethane, i.e., 2,2,6,6-tetramethyl-3,5-heptanedione (Hthd). In some embodiments, the beta diketonate comprises hexafluoroacetylacetone (Hfac). In some embodiments, the beta diketonate comprises acetylacetone (Hacac). In some embodiments, the beta diketonate comprises dipivaloylmethane (Hthd).

Alternatively, the cleaning agent may comprise a cyclopentadienyl group, such as a substituted or unsubstituted cyclopentadienyl group. Exemplary substituted cyclopentadienyl groups comprise alkyl substituted cyclopentadienyl groups such as methyl-substituted cyclopentadienyl, ethyl-substituted cyclopentadienyl, isopropyl-substituted cyclopentadienyl, and isobutyl-substituted cyclopentadienyl. Alternatively, the cleaning agent may comprise a carbonyl group. In some embodiments, the cleaning agent comprises carbon monoxide. In some embodiments, the cleaning agent comprises cyclopentadiene. In some embodiments, the cleaning agent comprises a mixture of one or more cyclopentadienyl-containing compounds. In some embodiments, the cleaning agent comprises one or more carbonyl-containing compounds. In some embodiments, the cleaning agent consists of a mixture of cyclopentadiene and carbon monoxide.

In some embodiments, the cleaning agent comprises a β-ketoamine, for example acetylacetonamine or 4-amino-1,1,1,5,5,5-hexafluoropentane-2-one.

In some embodiments, the cleaning agent comprises a β-dithione or a β-dithioketone. An exemplary β-dithione is 1,1,1,5,5,5-hexafluoropentane-2,4-dithione.

In some embodiments, the cleaning agent comprises a β-diimine. An exemplary β-diimine is 1,1,1,5,5,5-hexafluoropentane-2,4-diimine.

In some embodiments, the cleaning agent comprises an amino thione, e.g., a compound comprising a thione group and an amine group at a beta position. Exemplary amino thiones include 4-amino-3-pentene-2-thione and 4-amino-1,1,1,5,5,5-hexafluoropentane-2-thione.

In some embodiments, the cleaning agent comprises a β-thione imine. In some embodiments, the cleaning agent comprises a β-thioketone imine. Suitable β-thione imines include 1,1,1,5,5,5-hexafluoropentane-2-thione-4-imine.

In some embodiments, the cleaning agent comprises a carboxylic acid. Suitable carboxylic acids include formic acid.

In some embodiments, the cleaning agent comprises a cyclopentadienyl group.

In some embodiments, the cleaning agent comprises carbon monoxide.

In some embodiments, the cleaning agent comprises a carboxylic acid.

In some embodiments, the cleaning agent comprises formic acid.

In some embodiments, the cleaning agent can be provided to the reaction chamber as a mixture comprising the cleaning agent and H₂. For example, the cleaning agent can be provided to the reaction chamber in a gas stream comprising from at least 10 volume % (vol. %) H₂ to at most 90 vol. % H₂, or from at least 10 vol. % H₂ to at most 30 vol. % Hz, or from at least 30 vol. % H₂ to at most 50 vol. % Hz, or from at least 50 vol. % H₂ to at most 70 vol. % Hz, or from at least 70 vol. % H₂ to at most 90 vol. % H₂.

In some embodiments, the cleaning agent can be provided to the reaction chamber as a mixture comprising the cleaning agent and CO₂. For example, the cleaning agent can be provided 14 to the reaction chamber in a gas stream comprising from at least 10 volume % (vol. %) CO₂ to at most 90 vol. % CO₂, or from at least 10 vol. % CO₂ to at most 30 vol. % CO₂, or from at least 30 vol. % CO₂ to at most 50 vol. % CO₂, or from at least 50 vol. % CO₂ to at most 70 vol. % CO₂, or from at least 70 vol. % CO₂ to at most 90 vol. % CO₂.

In some embodiments, the cleaning agent can be provided to the reaction chamber in a gas stream comprising from at least 10 volume % (vol. %) cleaning agent to at most 90 vol. % cleaning agent, or from at least 10 vol. % cleaning agent to at most 30 vol. % cleaning agent, or from at least 30 vol. % cleaning agent to at most 50 vol. % cleaning agent, or from at least 50 vol. % cleaning agent to at most 70 vol. % cleaning agent, or from at least 70 vol. % cleaning agent to at most 90 vol. % cleaning agent. The remainder of the gas stream can comprise a further gas. Exemplary further gasses include H₂ and CO₂.

Providing the cleaning agent to the reaction chamber mixed with a further gas such as H₂ and CO₂ can advantageously prevent re-deposition of metal contaminants after they have been removed from the substrate using the cleaning agent. The further gas may be a decomposition product of the cleaning agent. Without the presently disclosed methods or devices being limited to any particular theory or mode of operation it is believed that, when formic acid is used as a cleaning agent, e.g., at a temperature of from at least 150′C to at most 275° C., or at a temperature of at least 170° C. to at most 230° C., formic acid may spontaneously decompose into H₂ and/or CO₂ during the cleaning step. By mixing formic acid with one or more of its decomposition products, i.e., H₂ and CO₂, it is believed that the decomposition of formic acid may be slowed down or prevented, thereby improving cleaning uniformity.

The disclosure is further explained by the following exemplary embodiments depicted in the drawings. The illustrations presented herein are not meant to be actual views of any particular material, structure, or device, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

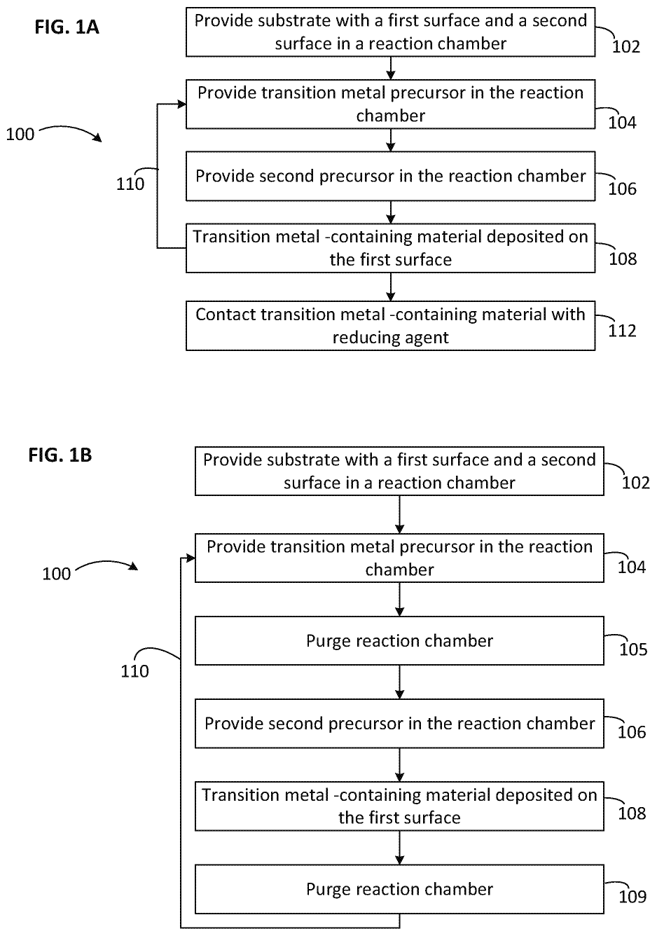

### FIG. 1A

FIG. 1A presents a process flow diagram of an exemplary embodiment of a method of depositing a transition metal-containing material on a substrate by a cyclic vapor deposition method 100 according to the current disclosure.

The method 100 may begin with a process block 102 which comprises, providing a substrate into a reaction chamber. The substrate may be heated to a deposition temperature. For example, the substrate may comprise one or more partially fabricated semiconductor device structures, the reaction chamber may comprise an atomic layer deposition reaction chamber, and the substrate may be heated to a deposition temperature from about 175 to about 300. The deposition temperature may be, for example, from about 200° C. to about 275° C., such as 225° C. or 250° C. In addition, the pressure within the reaction chamber may be controlled. For example, the pressure within the reaction chamber during the cyclic deposition process may be less than 1000 mbar, or less than 100 mbar, or less than 10 mbar, or less than 5 mbar, or even, in some instances less than 1 mbar.

The method 100 may continue with a process block 104, in which a transition metal precursor is provided into the reaction chamber. When a transition metal precursor is provided into the reaction chamber, the transition metal precursor may come into contact with the substrate for a time period (the pulse time) from about 0.05 seconds to about 60 seconds. In some embodiments, the transition metal compound may contact the substrate for a time period of between about 0.05 seconds and about 10 seconds, or between about 0.1 seconds and about 5 seconds. In addition, during the time for which the transition metal precursor is provided into the reaction chamber (i.e. pulse time), the flow rate of the transition metal precursor may be less than 2000 sccm, or less than 1000 sccm, or less than 500 sccm, or less than 200 sccm, or even less than 100 sccm.

The method 100 may continue with a process block 106 which comprises, contacting the substrate with a second precursor, such as an oxygen precursor, a nitrogen precursor, a silicon precursor, a phosphorous precursor, a selenium precursor, a boron precursor, sulfur precursor or a reducing agent. In some embodiments of the disclosure, the second precursor may contact the substrate for a time period of between about 0.01 seconds and about 60 seconds, or between about 0.05 seconds and about 10 seconds, or between about 0.1 seconds and about 5 seconds. In addition, during the pulsing of the second vapor phase reactant over the substrate, the flow rate of the second precursor may be less than 2000 sccm, or less than 1000 sccm, or less than 500 sccm, or less than 200 sccm, or even less than 100 sccm.

Providing transition metal precursor (block 104) and second precursor (block 106) in the reaction chamber, and thereby contacting them with the substrate leads to the deposition of transition metal-containing material on the first surface (block 108). Although depicted as a separate block, the transition metal-containing material may be continuously deposited as the second precursor is provided in the reaction chamber. The actual rate of deposition rate and its kinetics may vary according to process specifics. Depending on the specific material being deposited, and the composition of the first surface and the second surface, the selectivity of the process may vary.

The exemplary cyclic deposition method 100 wherein transition metal-containing material is selectively deposited on the first surface of the substrate relative to the second surface of the substrate by alternatively and sequentially contacting the substrate with the transition metal precursor (process block 104) and the second precursor (process block 106) may constitute one deposition cycle. In some embodiments, the method of depositing a transition metal containing material may comprise repeating the deposition cycle one or more times (process block 110). The repetition of the deposition cycle is determined based on the thickness of the transition metal-containing material deposited. For example, if the thickness of the transition metal-containing material is not sufficient for the desired device structure, then the method 100 may return to the process block 104 and the processes of contacting the substrate with the transition metal precursor 104 and contacting the substrate with the second precursor 106 may be repeated one or more times (block 110). Once the transition metal-containing material has been deposited to a desired thickness, the method may be stopped, and the transition metal-containing material and the underlying semiconductor structure may be subjected to additional processes to form one or more device structures.

In some embodiments the materials comprising a transition metal deposited according to methods described herein may be continuous on the first surface at a thickness below approximately 100 nm, or below approximately 60 nm, or below approximately 50 nm, or below approximately 40 nm, or below approximately 30 nm, or below approximately 25 nm, or below approximately 20 nm, or below approximately 15 nm, or below approximately 10 nm, or below approximately 5 nm, or lower. The continuity referred to herein can be physically continuity or electrical continuity. In some embodiments the thickness at which a material may be physically continuous may not be the same as the thickness at which a material is electrically continuous, and the thickness at which a material may be electrically continuous may not be the same as the thickness at which a material is physically continuous.

In some embodiments, a transition metal-containing material deposited according to some of the embodiments described herein may have a thickness from about 10 nm to about 100 nm. In some embodiments, a transition metal-containing material deposited according to some of the embodiments described herein may have a thickness from about 1 nm to about 10 nm. In some embodiments, the transition metal-containing material may have a thickness of less than 10 nm. In some embodiments, a transition metal-containing material deposited according to some of the embodiments described herein may have a thickness from about 10 nm to about 50 nm. In some embodiments, a transition metal containing material deposited according to some of the embodiments described herein may have a thickness greater than about 20 nm, or greater than about 40 nm, or greater than about 40 nm, or greater than about 50 nm, or greater than about 60 nm, or greater than about 100 nm, or greater than about 250 nm, or greater than about 500 nm. In some embodiments, a transition metal-containing material deposited according to some of the embodiments described herein may have a thickness of less than about 50 nm, less than about 30 nm, less than about 20 nm, less than about 15 nm, less than about 10 nm, less than about 5 nm, less than about 3 nm, less than about 2 nm, or even less than about 1 nm.

After a transition metal-containing material has been sufficiently deposited, the deposited material may optionally be reduced at block 112. Alternatively, the deposited material may be reduced already during the deposition (not depicted). In some embodiments, reducing the deposited material may also improve the selectivity of the process, by removing possible deposited material from the second surface.

### FIG. 1B

FIG. 1B is a process flow diagram of an exemplary embodiment of a method of depositing a transition metal-containing material on a substrate according to the current disclosure. The process follows the outline depicted for FIG. 1A, but it comprises purging the reaction chamber (block 105) after transition metal precursor has been provided in the reaction chamber (104). In other words, after contacting the substrate with the transition metal precursor at block 104, excess transition metal precursor and any reaction byproducts may be removed from the reaction chamber by a purge process.

The reaction chamber is purged (block 109) also following providing the second precursor in the reaction chamber. If the cyclic deposition process is repeated (block 110), the second purge (109) may be followed by providing the transition metal precursor in the reaction chamber (104). In other words, after contacting the substrate with the second precursor (block 106), the excess second precursor and any reaction byproducts may be removed from the reaction chamber by a purge process.

As a non-limiting example, Co-containing material may be selectively deposited on in situ-deposited TiN relative to native silicon oxide by pulsing CoCl₂(TMEDA) and TBH in an alternate and sequential manner into a reaction chamber. The substrate may be pre-cleaned with H₂ flown in the reaction chamber at the deposition temperature. The deposition temperature, indicated in this embodiment as the temperature of the susceptor, may be 275° C. The transition metal precursors may be pulsed (i.e. provided) in the reaction chamber for 2 seconds, after which the reaction chamber may be purged for 2 seconds. Then, TBH may be pulsed in the reaction chamber for 0.3 seconds, followed by a purge step of 2 seconds. The cycle may be repeated for 75 to 1,500 times to obtain a layer of cobalt-containing material. The deposited cobalt-containing material may comprise between 60 and 80 at. % cobalt, and between 10 to 30 at. % nitrogen. The resistivity of such material may be between 15 and 85 μΩcm. Using the methods described herein, it may be possible to deposit up to 10 nm, or up to 20 nm or up to 30 nm transition metal-containing material on metal, such as on copper with no growth on the dielectric material.

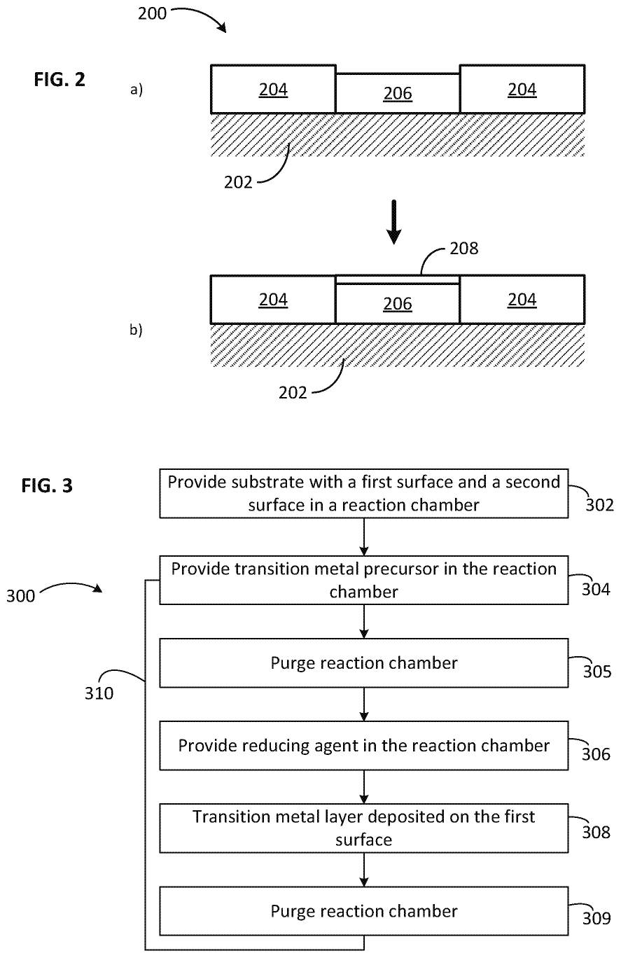

### FIG. 2

FIG. 2, panels a and b, illustrates a partially fabricated semiconductor device structure 200 as a simplified schematic illustration. The structure 200 comprises a substrate 202 and a dielectric material 204 formed over the substrate 202. The dielectric material may comprise a low dielectric constant material, i.e., a low-k dielectric. A trench may be formed in the dielectric material 204 and a metal interconnect material 206 may be formed in the trench to electrically interconnect a plurality of device structures disposed in substrate 202. In some embodiments, barrier material (not shown in FIG. 2) may be disposed on the surface of the trench to prevent the diffusion of the metal interconnect material. In some embodiments, the metal interconnect material 206 may comprise one or more of copper, cobalt or molybdenum.

In addition to the use of cobalt as a barrier material, cobalt may also be utilized as a capping layer. Therefore, with reference to FIG. 2, panel b, the structure 200 may also include a capping layer 208 disposed directly on the upper surface of the metal interconnect material 206. The capping layer 208 may be utilized to prevent oxidation of the metal interconnect material 206 and importantly prevent the diffusion of the metal interconnect material 206 into additional materials formed over the structure 200 in subsequent fabrication processes. In some embodiments of the disclosure, the capping layer 208 may also comprise cobalt. The thickness of a capping layer may vary from below 1 nm to several nm. In some embodiments, the metal interconnect material 206, the barrier material and the capping layer 208 may collectively form an electrode for the electrical interconnection of a plurality of semiconductor devices disposed in the substrate 202.

### FIG. 3

FIG. 3 illustrates an exemplary embodiment of a method of selectively depositing a transition metal layer on a substrate 300 according to the current disclosure. In blocks 302 and 304, a substrate is provided in a reaction chamber and a transition metal precursor is provided in the reaction chamber, respectively, as explained for FIG. 1. After providing a transition metal precursor in the reaction chamber (304), excess precursor and/or any reaction by-products may be removed by purging the reaction chamber (block 305).

When a transition metal layer is to be deposited on the substrate, a reducing agent may be provided in the reaction chamber (block 306) after providing the transition metal precursor (304) and optional purging (305). In some embodiments, the reducing agent is nitrogen-free. In some embodiments, the reducing agent may be a carboxylic acid. In some embodiments, the carboxylic acid may be formic acid.

As a non-limiting example, elemental cobalt may be deposited on a substrate comprising a copper surface as a first surface and a thermal silicon oxide as a second surface. The transition metal precursor may comprise CoCl₂(TMEDA), and the second precursor may be formic acid. In some embodiments, the purity of the formic acid may be at least 95%, such as 99%. Before deposition, the substrate may be cleaned by repeatedly pulsing formic acid into the reaction chamber at a temperature of 275° C. Co may be deposited by pulsing the transition metal precursor in the reaction chamber for 8 seconds, purging the reaction chamber for 5 seconds, and pulsing the second precursor in the reaction chamber for 3 seconds, after which the reaction chamber is purged for 5 seconds. This deposition cycle may be repeated for 500 to 1000 times. The carbon content of the deposited Co layer may be below 4 at. %, oxygen content below 2 at. %, and nitrogen content below detection limit (under 0.5 at. %). The deposition rate of Co may be between about 0.1 and about 0.2 A/cycle. Using the methods described herein, it may be possible to deposit up to 10 nm, or up to 20 nm or up to 30 nm transition metal layer on metal, such as on copper with no growth on the dielectric material.

In another non-limiting example, Co may be similarly deposited on Ru, while there is no deposition on thermal silicon oxide. A transition metal precursor may again be pulsed of 8 seconds, and a second precursor for 3 seconds at a temperature from 225° C. to 275° C., and the cycle may be repeated 400 times. This process may lead to deposition of 5 to 10 nm of elemental cobalt on the Ru surface. Without limiting the current disclosure to any specific theory, Co deposition on Ru may happen at a lower temperature than on Cu.

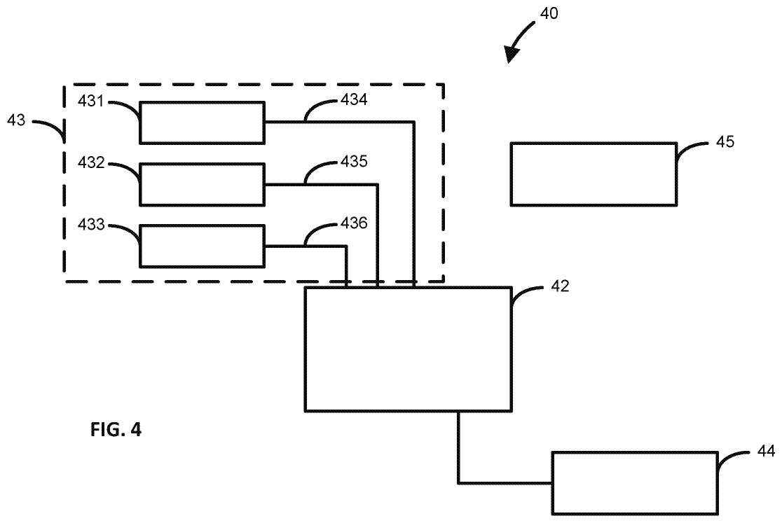

### FIG. 4

FIG. 4 is a schematic presentation of a vapor deposition assembly 40 according to the current disclosure. Deposition assembly 40 can be used to perform a method as described herein and/or to form a structure or a device, or a portion thereof as described herein.

In the illustrated example, deposition assembly 40 includes one or more reaction chambers 42, a precursor injector system 43, a transition metal precursor vessel 431, second precursor vessel 432, a purge gas source 433, an exhaust source 44, and a controller 45.

Reaction chamber 42 can include any suitable reaction chamber, such as an ALD or CVD reaction chamber.

The transition metal precursor vessel 431 can include a vessel and one or more transition metal precursors as described herein—alone or mixed with one or more carrier (e.g., inert) gases. Second precursor vessel 432 can include a vessel and a second precursor according to the current disclosure—alone or mixed with one or more carrier gases. Purge gas source 433 can include one or more inert gases as described herein. Although illustrated with three source vessels 431-433, deposition assembly 40 can include any suitable number of source vessels. Source vessels 431-433 can be coupled to reaction chamber 42 via lines 434-436, which can each include flow controllers, valves, heaters, and the like. In some embodiments, the transition metal precursor in the precursor vessel may be heated. In some embodiments, the vessel is heated so that the transition metal precursor reaches a temperature between about 150° C. and about 200° C., such as between about 160° C. and about 185° C., for example 165° C., 170° C., 175° C., or 180° C.

Exhaust source 44 can include one or more vacuum pumps.

Controller 45 includes electronic circuitry and software to selectively operate valves, manifolds, heaters, pumps and other components included in the deposition assembly 40. Such circuitry and components operate to introduce precursors, reactants and purge gases from the respective sources 431-433. Controller 45 can control timing of gas pulse sequences, temperature of the substrate and/or reaction chamber 42, pressure within the reaction chamber 42, and various other operations to provide proper operation of the deposition assembly 40. Controller 45 can include control software to electrically or pneumatically control valves to control flow of precursors, reactants and purge gases into and out of the reaction chamber 42. Controller 45 can include modules such as a software or hardware component, which performs certain tasks. A module may be configured to reside on the addressable storage medium of the control system and be configured to execute one or more processes.

Other configurations of deposition assembly 40 are possible, including different numbers and kinds of precursor sources and purge gas sources. Further, it will be appreciated that there are many arrangements of valves, conduits, precursor sources, and purge gas sources that may be used to accomplish the goal of selectively and in coordinated manner feeding gases into reaction chamber 42. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 40, substrates, such as semiconductor wafers (not illustrated), are transferred from, e.g., a substrate handling system to reaction chamber 42. Once substrate(s) are transferred to reaction chamber 42, one or more gases from gas sources 431-433, such as precursors, reactants, carrier gases, and/or purge gases, are introduced into reaction chamber 42 to effect a method according to the current disclosure.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of selectively depositing transition metal-containing material on a substrate by a cyclic deposition process, the method comprising
providing a substrate in a reaction chamber, wherein the substrate comprises a first surface comprising a first material, and a second surface comprising a second material;
providing a transition metal precursor comprising a transition metal halide compound in the reaction chamber in vapor phase; and
providing a second precursor in the reaction chamber in vapor phase to deposit a transition metal-containing material on the first surface relative to the second surface;

2. The method of claim 1, wherein the transition metal halide compound comprises a bidentate nitrogen-containing ligand.

3. The method of claim 1, wherein the transition metal halide compound comprises a transition metal chloride or a transition metal iodide or a transition metal fluoride.

4. The method of claim 1, wherein the transition metal in the transition metal halide compound is selected from a group consisting of manganese, iron, cobalt, nickel and copper.

5. The method of claim 1, wherein the first surface comprises a metal or a metallic material.

6. The method of claim 5, wherein the metal is a transition metal.

7. The method of claim 1, wherein the first surface comprises electrically conductive material.

8. The method of claim 1, wherein the second surface comprises dielectric material.

9. The method of claim 1, wherein the second precursor comprises an oxygen precursor.

10. The method of claim 1, wherein the second precursor comprises a nitrogen precursor.

11. A method of selectively depositing transition metal-containing material on a substrate by a cyclic deposition process, the method comprising
providing a substrate in a reaction chamber, wherein the substrate comprises a first surface comprising a first material, and a second surface comprising a second material;
providing a transition metal precursor comprising a transition metal compound in the reaction chamber in vapor phase; and
providing a second precursor in the reaction chamber in vapor phase to deposit transition metal-containing material on the first surface relative to the second surface;
wherein the transition metal compound comprises an adduct-forming ligand.

12. The method of claim 11, wherein the transition metal compound comprises at least one of CoCl₂(TMEDA), CoBr₂(TMEDA), CoI₂(TMEDA), CoCl₂(TMPDA), or NiCl₂(TMPDA).

13. A method of selectively depositing a transition metal layer on a substrate by a cyclic deposition process, the method comprising:
providing a substrate in a reaction chamber, wherein the substrate comprises a first surface comprising a first material, and a second surface comprising a second material;
providing a transition metal precursor comprising a transition metal halide compound in the reaction chamber in vapor phase;
providing a second precursor in the reaction chamber in vapor phase, wherein the second precursor comprises a nitrogen free compound, to deposit a transition metal layer on the first surface relative to the second surface;

14. The method of claim 13, wherein the second precursor comprises a carboxylic acid.

15. The method of claim 14, wherein the carboxylic acid is selected from a group consisting of formic acid, acetic acid, propanoic acid, benzoic acid and oxalic acid.

16. The method of claim 13, wherein a substantially continuous transition metal layer having a thickness of at least 20 nm is deposited on a first surface with substantially no deposition on the second surface.

17. The method of claim 13, wherein the transition metal precursor and the second precursor are provided in the reaction chamber in an alternate and sequential manner.

18. The method of claim 13, wherein the selectivity of the method is at least 80%.

19. The method of claim 13, wherein the method is a thermal deposition method.

20. The method of claim 13, wherein the transition metal-containing material or transition metal layer is formed at a temperature from about 175° C. to about 350° C.

21. The method of claim 13, wherein the reaction chamber is purged after providing a transition metal precursor and/or second precursor in the reaction chamber.

22. A vapor deposition assembly for depositing a transition metal-containing material on a substrate, the vapor deposition assembly comprising:
one or more reaction chambers constructed and arranged to hold a substrate comprising a first surface and a second surface, the first surface comprising a first material and the second surface comprising a second material;
a precursor injector system constructed and arranged to provide a transition metal precursor and a second precursor in the reaction chamber
a transition metal precursor source vessel constructed and arranged to hold a transition metal precursor in fluid communication with the reaction chamber;
a second precursor source vessel constructed and arranged to hold a transition metal precursor in fluid communication with the reaction chamber;
wherein the transition metal precursor comprises a transition metal halide compound and/or an adduct-forming ligand.
